(19) United States
(12) Patent Application Publication
(10) Pub. No.: US 2022/0115548 A1
(43) Pub. Date: Apr. 14, 2022

(54) LATTICE ANCHORING STABILIZES SOLUTION-PROCESSED SEMICONDUCTORS

(71) Applicant: QD SOLAR INC., TORONTO (CA)

(72) Inventors: MENGXIA LIU, CAMBRIDGE (GB); YUELANG CHEN, TORONTO (CA); FRANCISCO PELAYO GARCIA DE ARQUER, BARCELONA (ES); BIN SUN, TORONTO, ON (CA); SJOERD HOOGLAND, TORONTO (CA); EDWARD H. SARGENT, TORONTO (CA)

(21) Appl. No.: 17/287,629

(22) PCT Filed: Nov. 1, 2019
(86) PCT No.: PCT/CA2019/051554

§ 371 Date: Apr. 22, 2021

Related U.S. Application Data
(60) Provisional application No. 62/754,022, filed on Nov. 1, 2018.

(51) Int. Cl. H01L 31/0352; H01L 31/0368

(52) U.S. Cl. CPC H01L 31/035218; H01L 31/0368

(57) ABSTRACT

Disclosed herein are lattice-anchored materials that combine cesium lead halide perovskites with lead chalcogenide colloidal quantum dots (CQDs) that surprisingly exhibit stability exceeding that of the constituent materials. The CQDs keep the perovskite in its desired cubic phase, suppressing the transition to the undesired, lattice-mismatched, phases. These composite materials exhibit an order of magnitude enhancement in air stability for the perovskite, showing greater than six months' stability in room ambient as well as being stable for more than five hours at 200° C. in air. The perovskite prevents oxidation of the CQD surfaces and reduces the nanoparticles' agglomeration under 100° C. by a factor of five compared to CQD controls. The matrix-protected CQDs exhibit 30% photoluminescence quantum efficiency for a CQD solid emitting at infrared wavelengths. The lattice-anchored CQD:perovskite solid composite exhibits a doubling in charge carrier mobility as a result of a reduced energy barrier for carrier hopping compared to the pure CQD solid. These benefits indicate the potential of this new materials platform in solution-processed optoelectronic devices.

### FIELD

The present application concerns the technical field of thin-film photovoltaics and optoelectronic devices, and particularly to quantum dot nanocrystal films and solar cell devices. More particularly the present disclosure provides a method of stabilizing lead chalcogenide colloidal quantum dots (CQDs), such as lead sulphide (PbS) and lead selenide (PbSe) using a cesium lead halide perovskite CsPbX₃ (X=halide) outer shell structures.

### BACKGROUND

The stability of solution-processed semiconductors remains an important area for improvement on their path to wider deployment. Inorganic cesium lead halide perovskites have a bandgap well-suited to tandem solar cells¹; but suffer from an undesired phase transition in the vicinity of room temperature². Colloidal quantum dots (CQDs) are structurally robust materials prized for their size-tunable bandgap³; yet they too require further advances in stability, for they are prone to aggregation and surface oxidization at high temperatures as a consequence of incomplete surface passivation⁴.

Solution-processed semiconductors combine ease of processing, scalable fabrication, and compatibility with flexible substrates—compelling properties for next-generation optoelectronic devices. Given solution-processed materials' steadily-increasing performance in sensing, light-emissions and photovoltaics³, their limited stability is an increasingly urgent and important challenge. Much progress has been made toward the goal for the long-term stability in printable semiconductors⁶; however, their lifetime in room ambient and at elevated temperatures and humidity has not yet fulfilled the multi-thousand-hour stringent requirement for industrial applications.

Hybrid organic-inorganic perovskites—solution-processed, structurally soft materials⁷—have attracted intense interest especially as a result of their remarkable photovoltaic performance⁸. The best certified power conversion efficiency (PCE) of perovskite solar cells has rapidly advanced to 23.7%⁹. However, the limited environmental and thermal stability of perovskites remains an important challenge that—until it is addressed—threatens to hamper their widespread deployment in optoelectronics and energy harvesting. This instability stems from the volatility of perovskites' organic components, aggravated by external stress such as heat and light. An example of this is U.S. Pat. No. 10,181,538 to Ning et al. which uses a mixed organic-inorganic perovskite shell structure.

These issues can potentially be addressed using all-inorganic perovskites, of which cesium lead halide perovskite CsPbX₃ (X=halide) is a candidate of interest. Cubic-phase (α-phase) CsPbI₃ has a bandgap suited to tandem solar cells¹. Unfortunately, it transforms readily into the transparent orthorhombic phase (δ-phase) under ambient conditions at room temperature². This is associated with the low formation energy of the δ-phase at room temperature and the high flexibility of the perovskite lattice¹⁰. Substituting iodine with bromine improves the stability of cubic phase; however, mixed-halide perovskites undergo phase segregation when annealed at high temperature in air ambient. Approaches to stabilizing the α-phase CsPbX₃ perovskite are of urgent interest.

Colloidal quantum dots (CQDs)—also solution-processed and widely studied for optoelectronic applications—have a bandgap that is tuned via the quantum size effect across the wide solar spectrum³. Advanced materials processing strategies and device architectures have contributed to improved solar cell performance⁶; however, incomplete surface passivation leads to CQD aggregation and surface oxidation⁴, particularly when operated at high temperatures. These militate against device performance and lifetime.

Previously investigated methods to improve the stability of inorganic solution-processed materials have advanced each material system considerably. For α-phase CsPbX₃ perovskites, decreasing grain size and doping were proven useful for phase stabilization¹¹. However, the stability is still not satisfactory; and a large number of surface trap states are detrimental to their electronic properties. Moreover, stability under demanding accelerated lifetime conditions, such as 200° C. in air ambient, remains to be addressed.

For CQDs, improved air stability has been achieved using strongly bound surface ligands⁶. Unfortunately, the oxidation of sulfur-rich facets in lead sulfide CQDs occurs at temperatures as low as 50° C. and deteriorates device performance¹². Recent studies revealed that a monolayer of perovskite provided surface passivation of CQDs, a promising insight on the path to longer-term stability¹³; however, these perovskites failed to prevent oxidation and aggregation of the CQDs at high temperatures¹⁴.

In sum, ever more effective stabilization strategies are needed both in perovskites and CQDs.

### SUMMARY

Disclosed herein are lattice-anchored materials that combine cesium lead halide perovskites with lead chalcogenide CQDs that surprisingly exhibit stability exceeding that of the constituent materials. The inventors have discovered that CQDs keep the perovskite in its desired cubic phase, suppressing the transition to the undesired, lattice-mismatched, phases. These composite materials achieve an order of magnitude enhancement in air stability for the perovskite, reporting greater than six months' stability in room ambient; and also document more than five hours at 200° C. in air. The perovskite prevents oxidation of the CQD surfaces and reduces the nanoparticles' agglomeration under 100° C. by a factor of five compared to CQD controls. The matrix-protected CQDs exhibit 30% photoluminescence quantum efficiency for a CQD solid emitting at infrared wavelengths. The lattice-anchored CQD:perovskite solid composite exhibits a doubling in charge carrier mobility as a result of a reduced energy barrier for carrier hopping compared to the pure CQD Zo solid. These benefits indicate the potential of this new materials platform in solution-processed optoelectronic devices.

Thus, in an embodiment there is provided a composite material, comprising:

crystalline or polycrystalline particles embedded in a crystalline or polycrystalline shell material, the crystalline or polycrystalline shell material having first and second crystal phase structures, the first crystal structure being less thermodynamically stable than the second crystal phase structure, the composite material characterized in that the crystalline or polycrystalline shell material in the composite material exhibiting the first crystal phase structure and wherein the pre-formed crystalline or polycrystalline particles include lattice planes and the first crystal structure of the crystalline or polycrystalline shell material include lattice planes. The crystalline or polycrystalline particles and the crystalline or polycrystalline shell material being selected so that any lattice mismatch between the two lattice planes does not exceed 10%, and the crystalline or polycrystalline particle lattice planes and said crystalline or polycrystalline shell material lattice planes being substantially aligned such that the crystalline or polycrystalline particles and the crystalline or polycrystalline shell material are substantially atomically aligned. The crystalline or polycrystalline particles are present in the crystalline or polycrystalline shell material in a volume ratio from about 0.1 vol % to about 90 vol %.

The crystalline or polycrystalline particles and said crystalline or polycrystalline shell material may be selected so that any lattice mismatch between the two lattice planes does not exceed about 4%.

The crystalline or polycrystalline particles may be present in the crystalline or polycrystalline shell material in a volume ratio from about 1 vol % to about 90%.

The crystalline or polycrystalline shell material may have a thickness in a Zo range from about 0.5 nm to about 50 nm.

The crystalline or polycrystalline particles may have size in a range from about 1 nm to 100 nm.

The crystalline or polycrystalline particles may be lead chalcogenide based colloidal quantum dots, and wherein the crystalline or polycrystalline shell material may be an inorganic perovskite.

The colloidal quantum dots may be selected from the group consisting of lead sulphide (PbS) and lead selenide (PbSe).

The inorganic perovskite shell material may be selected from the group consisting of cesium (Cs), lead (Pb) halides.

The perovskite may be selected from the group consisting of any combination of cesium (Cs), rubidium (Rb), lead (Pb), chloride, bromide and iodide.

The crystalline or polycrystalline particles may be lead chalcogenide based colloidal quantum dots, and wherein said crystalline or polycrystalline shell material is an inorganic perovskite shell and wherein said composite material is incorporated into a photovoltaic cell, and wherein said collodial quantum dots are present in the perovskite shell in a volume ratio from about 80 vol % to about 90 vol %, said photovoltaic cell characterized in that the light absorbing component is the quantum dots.

The colloidal quantum dots may be selected from the group consisting of lead sulphide (PbS) and lead selenide (PbSe).

The perovskite may be selected from the group consisting of any combination of cesium (Cs), lead (Pb) halides.

The crystalline or polycrystalline particles may be lead chalcogenide based colloidal quantum dots, and the crystalline or polycrystalline shell material may be an Zo inorganic perovskite shell and wherein the composite material is incorporated into a photovoltaic cell, and wherein said collodial quantum dots are present in the inorganic perovskite shell in a volume ratio from about 0.5 vol % to about 5 vol %, said photovoltaic cell characterized in that the light absorbing component is the perovskite shell.

The colloidal quantum dots may be selected from the group consisting of lead sulphide (PbS) and lead selenide (PbSe).

The perovskite shell may be selected from the group consisting of cesium (Cs), lead (Pb) halides.

The crystalline or polycrystalline particles may be lead chalcogenide based colloidal quantum dots, and wherein said crystalline or polycrystalline shell material is an inorganic perovskite and wherein said composite material is incorporated into a light emitting diode device, and wherein said colloidal quantum dots are present in the perovskite shell in a volume ratio from about 10 vol % to about 25 vol %, and wherein said colloidal quantum dots are the light emitting medium. The colloidal quantum dots may be selected from the group consisting of lead sulphide (PbS) and lead selenide (PbSe). The perovskite may be selected from the group consisting of cesium (Cs), lead (Pb) halides.

The perovskite may be selected from the group consisting of any combination of cesium (Cs), rubidium (Rb), lead (Pb), chloride, bromide and iodide.

The colloidal quantum dots may have size in a range from about 1 nm to about 100 nm.

The composite material may be characterized in that the colloidal quantum dots are stabilized, by the inorganic perovskite shell, against thermally activated oxidation above room temperature up to a temperature of about 200° C.

A further understanding of the functional and advantageous aspects of the invention can be realized by reference to the following detailed description and drawings.

### BRIEF DESCRIPTION OF THE DRAWINGS

Embodiments disclosed herein will be more fully understood from the following detailed description thereof taken in connection with the accompanying drawings, which form a part of this application, and in which:

FIGS. 1A to 1D show characterization results which show epitaxial alignment between cesium lead halide perovskite and colloidal quantum dots, in which:

FIG. 1A is a schematic that depicts the atomistic model of CQD:perovskite lattice-anchored hybrid materials system,

FIG. 1B shows the lattice constant of lead chalcogenide CQDs and cesium lead halide perovskites of different stoichiometry,

FIG. 1C shows synchrotron X-ray diffractions of the CQDs with perovskite matrix showing the successful incorporation of CQD and perovskite components in the hybrid materials,

FIGS. 1D and 1E are HRTEM images of the lattice-anchored CQD:perovskite hybrid materials at high (FIG. 1D) and low (FIG. 1E) CQD concentration in which the perovskite shell has a lower contrast compared to CQDs, since the perovskite has a lower density than PbS; these images confirm the crystal structure and demonstrate the epitaxial orientational alignment at different facets.

FIGS. 2A to 2E show results of stability studies of CQD-anchored cesium lead Zo halide perovskites, in which:

FIG. 2A shows a schematic of phase transition and separation in cesium lead halide perovskites showing that the cubic to orthorhombic phase transition occurs at room temperature by exposure to moisture and air, and mixed halide perovskite samples, when heated to a high temperature in air, segregate into Br-rich and I-rich phases;

FIG. 2B shows the absorbance spectra of pristine CsPbBrI₂ film before and after annealing at 200° C. for five hours, showing that the high annealing temperature leads to a notable phase degradation and segregation, which is verified by the changes in absorbance and the shift of absorption edge, respectively;

FIG. 2C shows the stability of the lattice-anchored CsPbBrI₂ perovskite with different ratio of CQDs, in which the film stability is improved from three days to more than six months when 13 vol % CQDs are incorporated, the inset shows the X-ray diffraction of CsPbBrI₂ films with and without CQDs after stored in air for six months,

FIG. 2D shows the intensity loss in absorbance after five-hour annealing, and

FIG. 2E shows the shift in absorption edge after five-hour annealing in air.

FIGS. 3A to 3E show in-situ grazing-incidence small-angle x-ray scattering (GISAXS) measurements and PL studies of CQDs in lattice-anchored semiconductor films to track changes in CQD packing density and uniformity at elevated temperatures, in which:

FIGS. 3A and 3C show the GISAXS 2D pattern of the matrix-protected CQD film (FIG. 3A) and pristine film (FIG. 3C) measured at 70° C., in which the dark color represents the lower intensity and bright color represents the higher intensity,

FIGS. 3B and 3D show azimuthally-integrated intensities of the matrix-protected CQD (FIG. 3B) and pristine CQD film (FIG. 3D) showing the distribution of Zo inter-dot spacing at elevated temperatures, and

FIG. 3E shows the changes in photoluminescence (PL) intensity when different annealing times are applied.

FIGS. 4A to 4F show carrier transfer and energetics within lattice-anchored CQD-in-perovskite hybrid solids, in which:

FIGS. 4A to 4C show schematics of carrier transport in the case of low CQD loading (FIG. 4A), high CQD loading (FIG. 4B), and pure CQDs (FIG. 4C), in which the conduction and valence band of CQD solids reside within the bandgap of CsPbBrₓI₃₋ₓ matrix, forming a type I heterojunction, and at low CQD loading, the photocarriers generated in perovskite matrix transfer to embedded CQD solids, while at high CQD loading, the carriers tunnel through the perovskite matrix by overcoming an energy barrier,

FIG. 4D shows PL excitation spectra of CQDs, wherein the perovskite absorption region, the PL excitation intensity increases as matrix concentration increases, showing an efficient carrier transfer from matrix to CQDs,

FIG. 4E shows the PL and photoluminescence quantum efficiency (PLQE) of CQDs with different perovskite matrixes.

FIG. 4F shows carrier mobility measured by transient absorption spectroscopy, in which the matrix-infiltrated CQD films show a doubling in carrier mobility compared to pristine CQD films.

FIG. 5A to 5B shows the morphology of CQD:perovskite hybrid films, in which:

FIG. 5A shows photographs of as-prepared CsPbBr2I films with 0, 10 and 20 vol % of CQDs, from left to right, respectively;

FIG. 5B shows photographs of as-prepared CsPbBrI₂ films with 0, 10 and 20 vol % of CQDs, from left to right, respectively.

FIG. 5C to 5F shows SEM images of the CsPbBr₂I films, in which:

FIG. 5C shows the SEM image of the pure CsPbBr₂I film,

FIG. 5D shows the SEM image of the CQD:CsPbBr₂I hybrid film with 10 vol %,

FIG. 5E shows the SEM image of the CQD:CsPbBr₂I hybrid film with 20 vol %,

FIG. 5F shows the SEM image of the CQD:CsPbBr₂I hybrid film with 33 vol %, and

FIG. 5C to 5F shows that at low CQD loading (10 vol %), no significant changes were observed in grain size, giving evidence that there is not significant correlation between the grain size and stability. When CQD loading is higher than 20 vol %, a smaller grain size is observed, which is consistent with the XRD peak broadening shown in FIG. 1C.

FIG. 6A to 6F show EDX mapping and elemental analysis of CQD:CsPbBr₂I hybrid films, in which:

FIGS. 6A to 6C show the EDX mapping of CsPbBr2I films with various CQD vol %, in which:

FIG. 6A shows the EDX mapping of CsPbBr2I films with 10 vol % CQDs,

FIG. 6B: shows the EDX mapping of CsPbBr2I films with 20 vol % CQDs,

FIG. 6C shows the EDX mapping of CsPbBr2I films with 33 vol % CQDs, and

FIG. 6D to 6F show the elemental analysis of the films in FIG. 6A to 6C, in which the values from experiments and calculations are both presented in the inset table. The elemental ratios are normalized to Pb.

FIGS. 7A and 7B show the X-ray diffractions of the CQD:CsPbBr₂I films, which:

FIG. 7A shows two-dimensional grazing-incidence wide-angle X-ray scattering (GIWAXS) patterns of CQD:CsPbBr₂I films, and

FIG. 7B shows the azimuthal integrated line profile along the qz-axis of FIG. 7A.

FIG. 8A to 8D shows the morphological and structural characterization of CQD:perovskite hybrid structures, in which:

FIG. 8A shows the HRTEM image of PbS quantum dots with thin CsPbBrI₂ perovskite shell, the shell has a lower contrast compared to CQDs, since CsPbX₃ has a lower density than PbS,

FIG. 8B shows the FFT images of the image of FIG. 8A,

FIG. 8C shows the scanning TEM image (left) and EELS elemental mapping of CQD/CsPbBrI2 core-shell structure, and

FIG. 8D shows the scanning TEM image (left) and EELS elemental mapping of CQD-in-CsPbBrI₂-matrix.

FIG. 9A to 9D show the stability studies of lattice-anchored and control materials system, in which:

FIG. 9A shows the stability of the lattice-anchored perovskite with mixed halides. The film stability is improved from a few days to several months by increasing the CQD %. For Br content higher than 33%, the perovskite film could be stabilized in room ambient for more than six months without any degradation.

FIG. 9B shows the stability of the lattice-anchored α-phase CsPbI₃. The CsPbI₃ film exhibits one-thousand-hour air stability for the pure perovskite matrix. CQDs further enhanced the stability to greater than six months, showing the compatibility of this strategy with other previous-built methods.

FIG. 9C to 9D show thermal stability studies of MAPbI₃ films with and without CQDs.

FIG. 9C shows the absorption spectra of pure MAPbI₃ perovskites, before and after annealing in ambient air where the degradation of MAPbI₃ perovskite arises due to the volatility of organic components, and

FIG. 9D shows the absorption spectra of MAPbI₃ perovskites with 10 vol % CQDs, before and after annealing in ambient air. The CQD:MAPbI₃ film does not show any improvement in thermal stability compared to pure MAPbI₃. The reduced and broadened excitonic peak of PbS shows an increase in CQD aggregation.

FIG. 10A shows the GISAXS 2D pattern of the matrix-protected CQD film measured at room temperature.

FIG. 10B shows the GISAXS 2D pattern of the pristine CQD film measured at room temperature.

FIG. 11A to 11C show the photophysical studies of CQD-in-matrix hybrid films, in which:

FIG. 11A shows the absorption spectra of CsPbBrI₂ film with and without CQDs embedded,

FIG. 11B shows the PL quenching at perovskite emission range. When CQDs are embedded, the PL signal from perovskite is completely quenched, showing an efficient carrier transfer from matrix to CQDs, and

FIG. 11C shows the PL quantum yield of CQD-in-matrix films at different CQD ratios.

FIG. 12A to 12D show the mobility studies based on the dependence of carrier lifetime on trap percentage, in which:

FIG. 12A shows the time traces at the exciton bleach peak of 960 nm bandgap matrix-protected CQD donor films with a range of acceptor CQD concentrations, increasing from top (0%) to bottom (5%),

FIG. 12B shows the data from FIG. 12A with fits after subtracting Auger dynamics from the pure donor film, with fitted values for lifetime and offset Data with fits after subtracting Auger dynamics from the pure donor film, with fitted values for lifetime and offset,

FIG. 12C shows the time traces at the exciton bleach peak of 960 nm bandgap pristine CQD donor films with a range of acceptor CQD concentrations, increasing from top (0%) to bottom (5%), and

FIG. 12D shows the data from FIG. 12C with fits after subtracting Auger dynamics from the pure donor film, with fitted values for lifetime and offset Data with fits after subtracting Auger dynamics from the pure donor film, with fitted values for lifetime and offset.

FIG. 13A to 13D show the CQD solar cell devices and performance, in which:

FIG. 13A shows the device architecture,

FIG. 13B shows the J-V curves of the matrix-infiltrated CQD samples (dark curve), and the pure CQD samples (light curve),

FIG. 13C shows the EQE curves of the matrix-infiltrated CQD samples (dark curve), and the pure CQD samples (light curve), and

FIG. 13D shows the stability tests under continuous AM1.5G illumination with the matrix-infiltrated CQD samples (dark curve) and pure CQD samples (light curve) not encapsulated.

### DETAILED DESCRIPTION

Without limitation, the majority of the systems described herein are directed to multibandgap nanocrystal ensembles for solar-matched energy harvesting. As required, embodiments of the present invention are disclosed herein. However, the disclosed embodiments are merely exemplary, and it should be understood that the invention may be embodied in many various and alternative forms.

The accompanying figures, which are not necessarily drawn to scale, and which are incorporated into and form a part of the instant specification, illustrate several aspects and embodiments of the present disclosure and, together with the description therein, serve to explain the principles of the process of producing multibandgap nanocrystal ensembles for solar-matched energy harvesting. The drawings are provided only for the purpose of illustrating select embodiments of the apparatus and as an aid to understanding and are not to be construed as a definition of the limits of the present disclosure. For purposes of teaching and not limitation, the illustrated embodiments are directed to multibandgap nanocrystal ensembles for solar-matched energy harvesting.

As used herein, the terms, “comprises” and “comprising” are to be construed as being inclusive and open ended, and not exclusive. Specifically, when used in the specification and claims, the terms, “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately”, when used in conjunction with ranges of dimensions of particles, compositions of mixtures or other physical properties or characteristics, are meant to cover slight variations that may exist in the upper and lower limits of the ranges of dimensions so as to not exclude embodiments where on average most of the dimensions are satisfied but where statistically dimensions may exist outside this region. It is not the intention to exclude embodiments such as these from the present disclosure.

As used herein, the phrase colloidal quantum dots refers to semiconducting particles that have a size below the Exciton Bohr radius. Quantum dot bandgaps may range from about 0.5 electron Volts (eV) to about 3 eV, and may include but are not limited to, PbS, PbSe, Ag₂S, Ag₂Se, to mention just a few.

As used herein, the phrase “interparticle separation” refers to the shortest distance from the surface of one quantum dot to that of the adjacent quantum dot.

Broadly, the present disclosure discloses a composite material which includes a pre-formed crystalline or polycrystalline particles embedded in a crystalline or polycrystalline shell material. The crystalline or polycrystalline shell material is characterized by having at least two crystal phase structures in which a first crystal structure is less thermodynamically stable than the second crystal phase structure. The composite material is characterized by the fact that the crystalline or polycrystalline shell material in the composite material exhibits the first crystal phase structure and where the pre-formed crystalline or polycrystalline particles include lattice planes and the first crystal structure of the crystalline or polycrystalline shell material include lattice planes. The pre-formed crystalline or polycrystalline particles and the crystalline or polycrystalline shell material are selected so that any lattice mismatch between the two lattice planes does not exceed 10%. The lattice planes of the pre-formed crystalline or polycrystalline particle and the crystalline or polycrystalline shell material are substantially aligned in the finally formed composite such that the pre-formed crystalline or polycrystalline particles and the crystalline or polycrystalline shell material are substantially atomically aligned. The pre-formed crystalline or polycrystalline particles are present in the crystalline or polycrystalline shell material in a volume ratio from about 0.1 vol % to about 90 vol %.

In some embodiments the pre-formed crystalline or polycrystalline particles and the crystalline or polycrystalline shell material are selected so that any lattice mismatch between the two lattice planes does not exceed about 4%.

In some embodiments the pre-formed crystalline or polycrystalline particles are present in the crystalline or polycrystalline shell material in a volume ratio from about 1 vol % to about 90%.

In some embodiments the crystalline or polycrystalline shell material has a thickness in a range from about 0.5 nm to about 50 nm.

In some embodiments the pre-formed crystalline or polycrystalline particles have size in a range from about 1 nm to 100 nm.

In preferred embodiments the pre-formed crystalline or polycrystalline particles are lead chalcogenide based colloidal quantum dots, and wherein said crystalline or polycrystalline shell material is an inorganic perovskite. These colloidal quantum dots may be lead sulphide (PbS) and lead selenide (PbSe), or combinations thereof.

In preferred embodiments the inorganic perovskite shell material is a cesium (Cs), lead (Pb) halide, and the inorganic perovskite is selected from the group Zo consisting of any combination of cesium (Cs), rubidium (Rb), lead (Pb), chloride, bromide and iodide.

In an embodiment, the pre-formed crystalline or polycrystalline particles are lead chalcogenide based colloidal quantum dots, and the crystalline or polycrystalline shell material is an inorganic perovskite shell. A photovoltaic cell can be produced or constructed incorporating or using these particles. In one embodiment of this photovoltaic cell the collodial quantum dots are present in the inorganic perovskite shell in a volume ratio from about 80 vol % to about 90 vol %. When constructed with a volume ratio in this range, the light absorbing component in the cell is the quantum dots.

In another embodiment of a photovoltaic cell, the quantum dots are present in the inorganic perovskite shell in a volume ratio from about 0.5 vol % to about 5 vol %, in which case the light absorbing component is the perovskite shell.

Alternatively, coated quantum dots may be assembled into a light emitting diode (LED). In this device the colloidal quantum dots are present in the perovskite shell in a volume ratio from about 10 vol % to about 25 vol %, and in this LED device colloidal quantum dots are the light emitting medium.

In an embodiment of these photovoltaic and LED devices colloidal quantum dots are lead sulphide (PbS) and/or lead selenide (PbSe) quantum dots, and the inorganic perovskite is a cesium (Cs), lead (Pb) halide.

In some embodiments the inorganic perovskite includes any combination of cesium (Cs), rubidium (Rb), lead (Pb), chloride, bromide and iodide.

In embodiment of these PV and LED devices the colloidal quantum dots have size in a range from about 1 nm to about 100 nm.

A very beneficial advantage of these composite materials is that the colloidal quantum dots are stabilized, by the inorganic perovskite shell, against thermally activated oxidation above room temperature up to a temperature of about 200° C.

Embodiments of the present composite materials will be studied, characterized and assembled into a photovoltaic device elucidated in the non-limiting Example below.

### NON-LIMITING EXAMPLE

### Methods and Characterization

### CQD Synthesis and Solution Ligand Exchange

CQDs were synthesized and washed using previously published methods¹⁵. A ligand-exchange process was carried out in the solution phase in an air ambient. The exchange solution was prepared by dissolving perovskite precursors (lead iodide 0.05 M, lead bromide 0.05 M, cesium iodide 0.1 M) and ammonium acetate (0.01 M) in N,N-dimethylformamide (DMF). CQD solution in octane (5-6 mg/mL) was added to the exchange solution in a 1:1 volume ratio. The mixed solution was vortexed vigorously for 3 min until CQDs completely transferred to DMF phase. The DMF solution was then washed three times using octane. After the exchange process, CQDs were precipitated via the addition of toluene, and then separated by centrifugation. This was followed by a drying process.

### Film Fabrication

The amount of perovskite matrix, and thus the average dot-to-dot distance, are tuned through the ratio of CQD to perovskite. For perovskite-dominant films with less than 15 vol % CQDs, the exchanged CQDs were redispersed in 0.4 M CsPbBrₓI₃₋ₓ perovskite precursor solution in a mixed solvent of 4:1 dimethyl sulfoxide (DMSO) to DMF. The CsPbI₃ matrix solution was prepared following a reported method². For CQD-dominant films with CQD loading above 30 vol %, matrix solution was added first to the exchanged CQDs, resulting in a partially dispersed CQD paste. Butylamine, a solvent widely used in CQD film fabrication, was then added to increase the solubility and disperse the dots completely. The hybrid ink was deposited by spin-coating at 2000 rpm for 60 s to achieve an optimized thickness. This was followed by an annealing process to crystallize the matrix and remove solvent residues. This method can be extended to a larger scale via spray coating and blade coating.

### High-Energy X-Ray Diffraction Measurements

CQD/perovskite samples were made using the abovementioned spin-coating process. High-energy X-ray diffraction experiments were conducted at the 6-ID-D beamline at Argonne National Laboratory, USA. The energy of the x-ray incident beam was 100.329 keV. The two-dimensional (2D) setup was applied for data collection with a Perkin Elmer model 1621 X-ray area detector. The results of the diffraction patterns were calculated using the Fit2D software.

### X-Ray Scattering Measurements

Grazing-incidence small-angle X-ray scattering (GISAXS) measurements were performed at the D1 beamline, Cornell High Energy Synchrotron Source (CHESS). The wavelength of the employed X-ray beam was 1.155 (Angstroms) (A). A wide bandpass (1.47%) double-bounce multilayer monochromator was used. The scattering patterns were obtained at a photon-incident angle of 0.5 degrees with Zo respect to the sample plane. A heating stage was set up for temperature-dependent in situ studies. The GISAXS scans were taken from 40° C. to 100° C. The annealing temperature was increased by 30° C. at a time, and kept at each temperature for 20 min.

Grazing-incidence wide-angle X-ray scattering (GIWAXS) measurements were performed at beamline 7.3.3 at the Advanced Light Source, Lawrence Berkeley National Laboratory. Wavelength of the employed X-ray beam was 1.24 Å. The scattering patterns were obtained at a photon-incident angle of 0.25 degrees with respect to the sample plane. Samples were scanned in a He environment to reduce air scattering. Exposure times were 30 seconds. The scattering patterns were recorded using a Pilatus 2M detector at a fixed distance of 277.674 mm. Calibration of the lengths in reciprocal space was done by using silver behenate. Samples for GISAXS and GIWAXS were spin-coated on glass substrates following the same spin coating and annealing procedures as were used in film fabrication.

### HRTEM and EELS Measurements

HRTEM samples were prepared by spin-coating the CQDs in perovskite precursor solution onto an ultrathin-carbon film (Ted Pella 01800-F). The samples were baked at 80° C. for 20 min and stored under high vacuum overnight. The HRTEM images and EELS elemental maps were then taken on a Hitachi HF-3300 instrument with 300 kV accelerating voltage observation condition.

### SEM and EDX Measurements

The morphologies and elemental maps of the prepared films were investigated using SEM and EDX on a Hitachi SU8230 apparatus.

### PL, PLQE and the Calculation of Carrier Transfer Efficiency

Photoluminescence (PL) measurements were carried out using a Horiba Fluorolog system. Steady-state PL and was acquired with a time-correlated single-photon-counting detector and a monochromatized xenon lamp excitation source. The film was placed at an incident angle of 30° away from the detector to avoid reflections of the incident beam.
The carrier transfer efficiency (q) was defined as:

$$η = \frac{{n}_{transfer}}{{n}_{total}}$$

where n_{transfer} is the number of charge carriers that are transferred into the CQDs from the perovskite, and nₜₒₜₐₗ is the total number of carriers photogenerated in the perovskite.
We measured the photoluminescence from CQDs in lattice-anchored matrix using two excitation wavelengths: a short wavelength that excites both CQDs and perovskite, and a long wavelength that only excites CQDs. The photoluminescence (PL) of CQDs in these two scenarios are

PL_{CQDs,short}=(A_{CQDs,short}+ηA_{p,short})×PLQE_{CQDs}×I_{ex,short} (1)

PL_{CQDs,long}=A_{CQDs,long}×PLQE_{CQDs}×I_{ex,short} (2)
PL_{CQDs} and Iₑₓ represent the photoluminescence yield from the CQDs (in photons per second) and the photon intensity of the excitation source (in photons per second), respectively. A_{CQDs} and Aₚ are the absorption of CQDs and perovskite component, respectively. From equations (1) and (2), we determine

$${η}_{total} = [ ( \frac{{PL}_{CDQs , short} \times {I}_{ex , long}}{{PL}_{CDQs , long} \times {I}_{ex , short}} ) \times {A}_{CDQs , long} - {A}_{CDQs , short} ] \frac{1}{{A}_{p , short}} \qquad ( 3 )$$

The measured values of PL_{CQDs}/Iₑₓ and absorption results are presented in Table 1.

TABLE 1
Photophysical parameters of lattice-anchored hybrid material.

| PL_{CQDs, short}/ | PL_{CQDs, long}/ | | | |
|---|---|---|---|---|
| I_{ex, short} | I_{ex, long} | A_{CQDs, short} | A_{CQDs, long} | A_{p, short} |
| 5135476 | 813487 | 0.11 | 0.07 | 0.38 |

Specifically, Table 1 shows the photophysical parameters of lattice-anchored hybrid materials. PL_{CQDs} and Iₑₓ represent the photoluminescence yield from the CQDs (in photons per second) and the photon intensity of the excitation source (in photons per second), respectively. A_{CQDs} and Aₚ are the absorption of CQDs and perovskite components, respectively.
Extraction of Mobility from Transient Absorption Spectroscopy (TAS)

Charge carrier mobilities were obtained with the aid of ultrafast and nanosecond transient absorption spectroscopy. The amplitude of the bandedge bleach signal in TAS is representative of the bandedge carrier population. When small-bandgap carrier-acceptor CQDs were added to large-bandgap carrier-donor CQDs at given concentrations (Nₜ), the change in donor CQD lifetime (τ) with varying Nₜ of acceptor CQDs provides the diffusion coefficient (D) and mobility (μ).

$$D = \frac{d}{6 σ ( τ \text{/} {N}_{t}^{- 1} )}$$

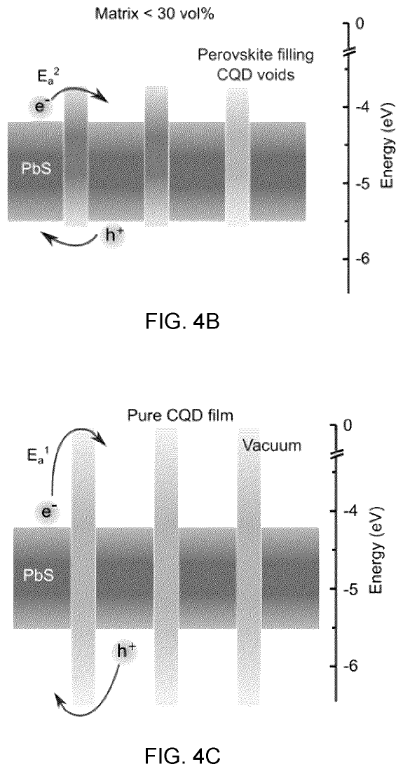

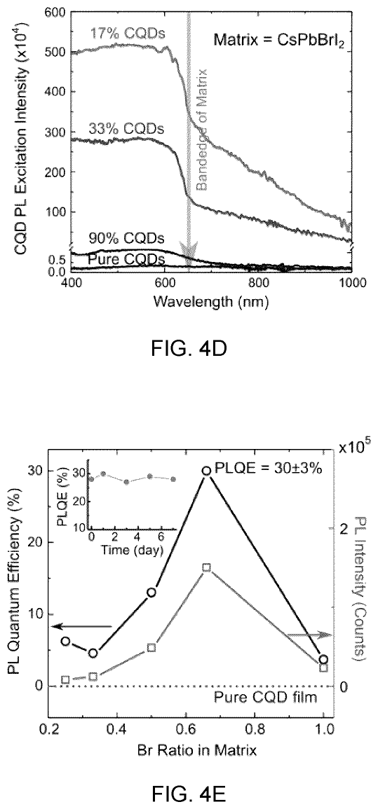

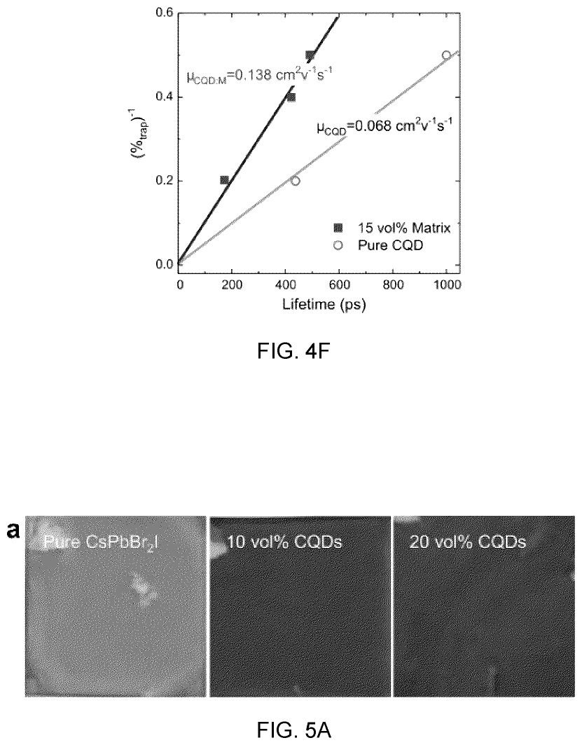

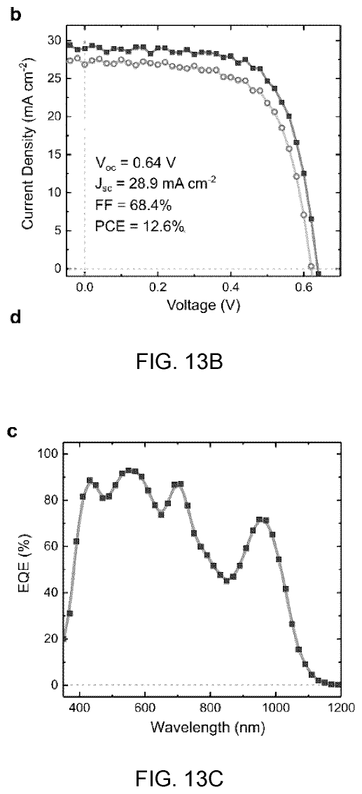

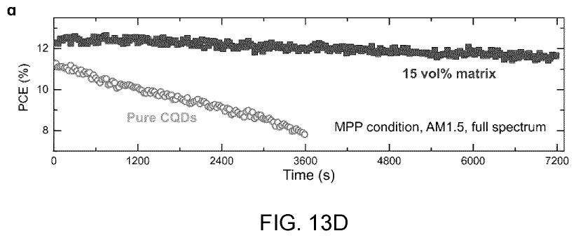

σ is the capture cross section, which for the 3D model is assumed to be ¼πd^{2 38}. Population transfer can be monitored directly by tracking the decay in the donor CQD bleach signals (FIGS. 13 and 14). When Nₜ⁻¹ is plotted against τ, the resulted slope is proportional to mobilities of carriers (FIG. 4F). The matrix-infiltrated CQD film shows a two-fold improvement in carrier mobility compared to pristine CQD films.

Transient absorption spectra were recorded using a femtosecond pump-probe spectroscopy. Femtosecond laser pulses were produced by a regeneratively amplified Yb:KGW laser at a 5 kHz repetition rate (Light Conversion, Pharos). By passing a portion of the 1030 nm fundamental through an optical parametric amplifier (Light Conversion, Orpheus) the pump pulse was generated. The second harmonic of the signal pulse was selected for 750 nm light. Both the pump pulse and probe (fundamental) were directed into an optical bench (Ultrafast, Helios), where a white-light continuum was generated by focusing the 1030 nm fundamental through a sapphire crystal. Low excitation fluence of (N)=0.001 was used to avoid the Auger recombination. The time delay (time resolution ˜350 fs) was adjusted by optically delaying the probe pulse, with time steps increasingly exponentially. A chopper was used to block every other pump pulse.

Each probe pulse was measured by a CCD after dispersion by a grating spectrograph (Ultrafast, Helios). Samples were prepared on glass substrate and translated at 1 mm/s during the measurement. Pump fluences were kept at 8 μJ/cm². Kinetic traces were fit to the convolution of the instrument response and a sum of exponential decays. Time zero was allowed to vary with wavelength to account for the chirp of the probe.

### Results

The present disclosure provides a method to block the phase transition of CsPbX₃ and have discovered that it is possible to prevent atomic site adjustment and lattice deformation by incorporating inclusions of CQDs that lattice-match to the desired, but otherwise unstable, α-solid, while being appreciably mismatched with the δ-phase.

The new hybrid material produced using the present method demonstrates a significant improvement in stability relative to the individual stability of each component. CQDs promote the epitaxial growth of α-phase perovskite and anchor the atoms of the perovskite to the CQD surfaces. This leads to improved ambient lifetime, which reaches greater than six months for the newly-stabilized CsPbX₃ perovskite. It also leads to significantly enhanced thermal stability in air, these composite materials do not degrade following exposure to 200° C. for five hours. This is fully an order of magnitude longer than for the pure perovskite absent the CQDs.

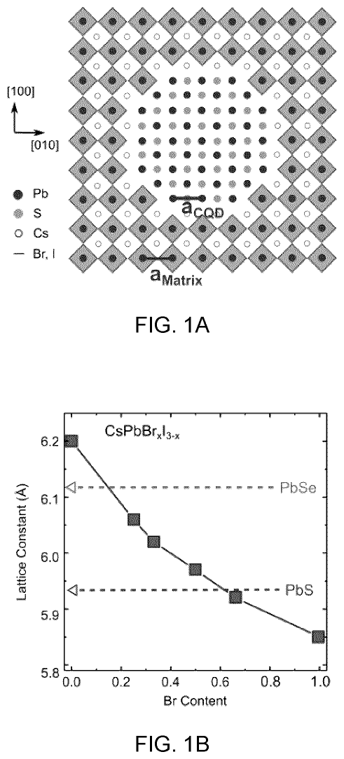

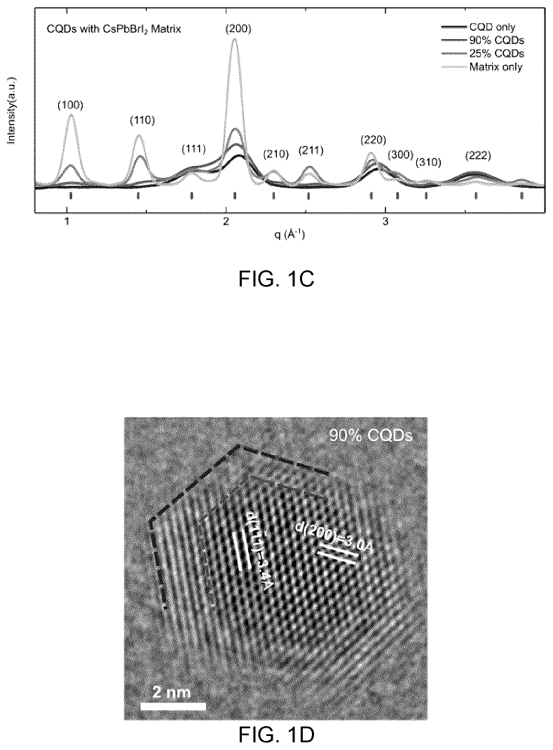

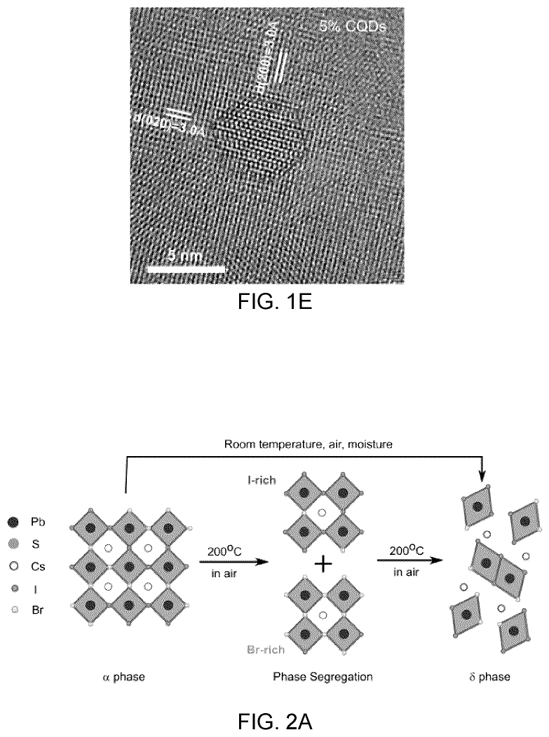

The CQD:perovskite lattice-anchored hybrid materials system is depicted in FIG. 1A. Lead chalcogenides, non-limiting examples being PbS and PbSe, with their rock salt structure have a Pb-Pb distance of 5.94 and 6.12 Å¹⁶, respectively, close to that of the α-phase CsPbBrₓI₃₋ₓ perovskite (5.85 Å to 6.21 Å)¹. By tuning the Br to I ratio in matrix composition, we achieve near-zero lattice mismatch (ε) for PbS CQDs at Br content ˜66% (ε<0.2%), enabling the strain-free epitaxial growth of perovskite (see FIG. 1B).

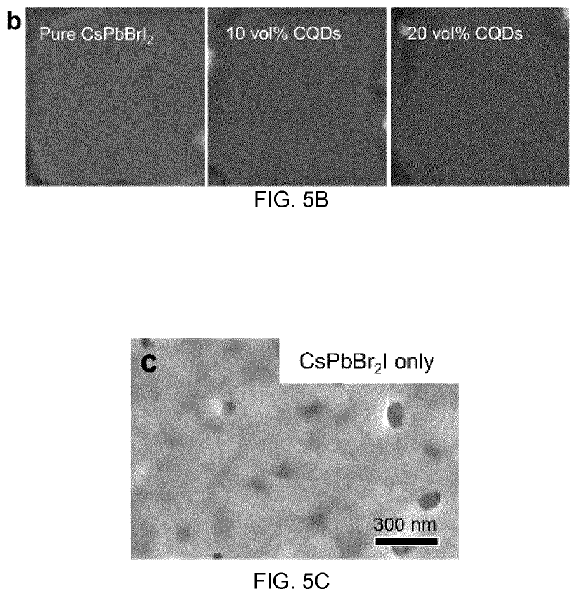

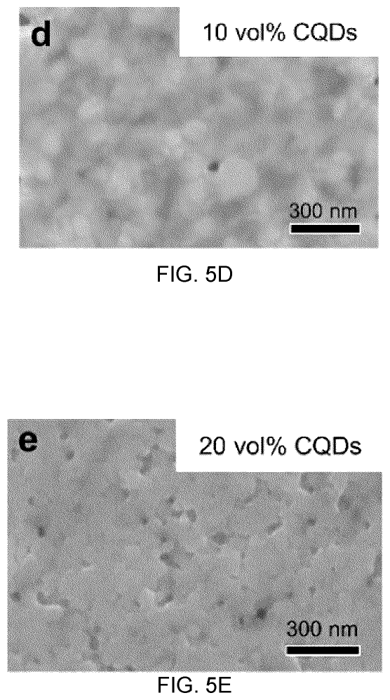

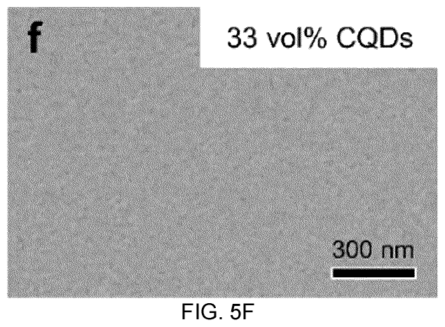

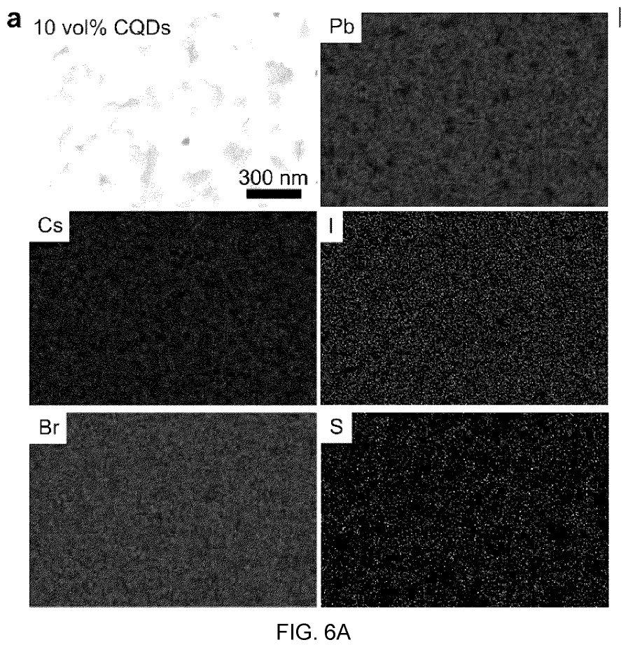

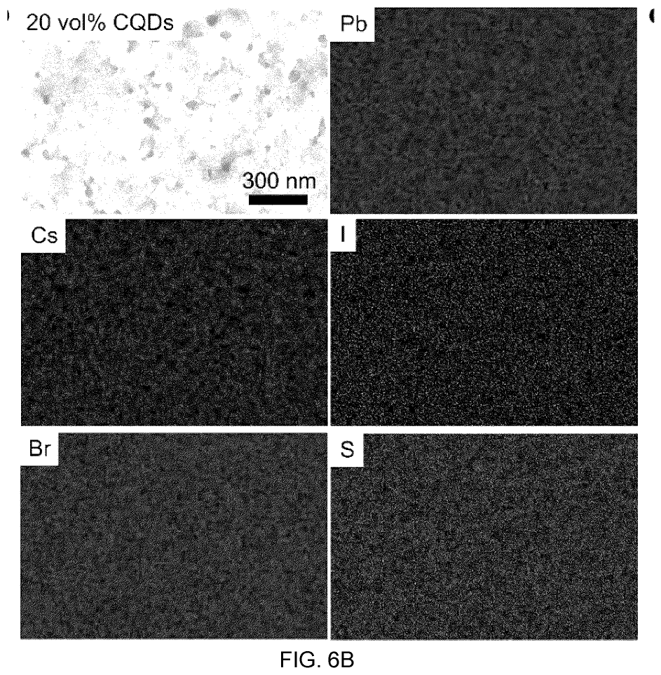

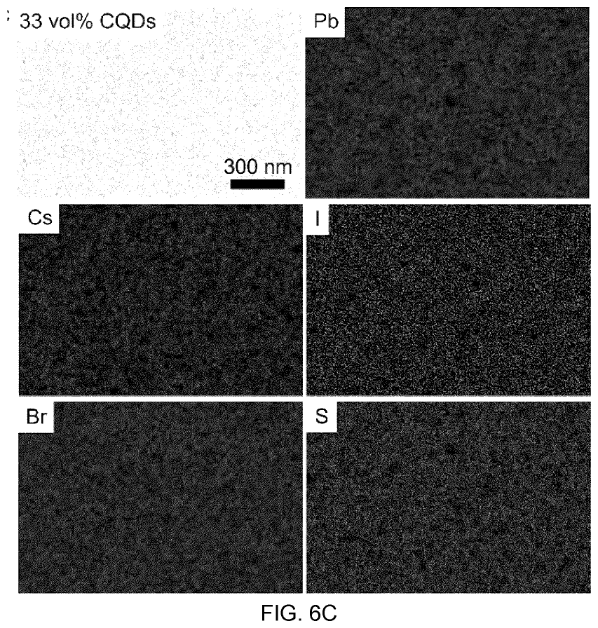

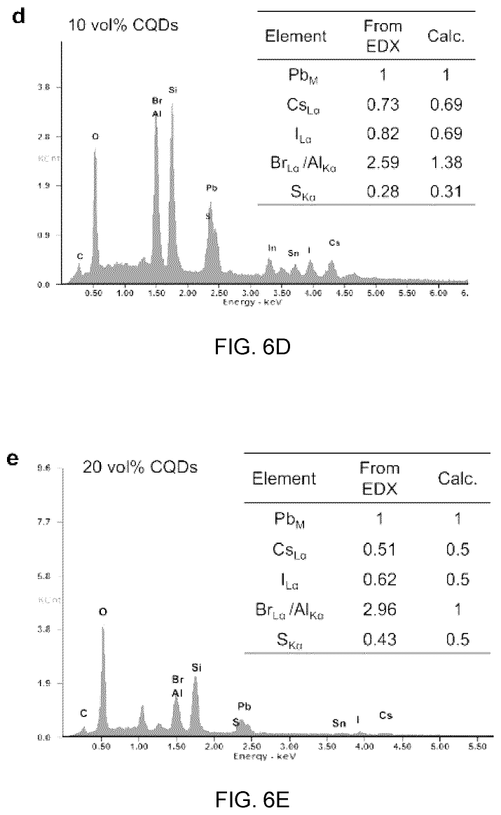

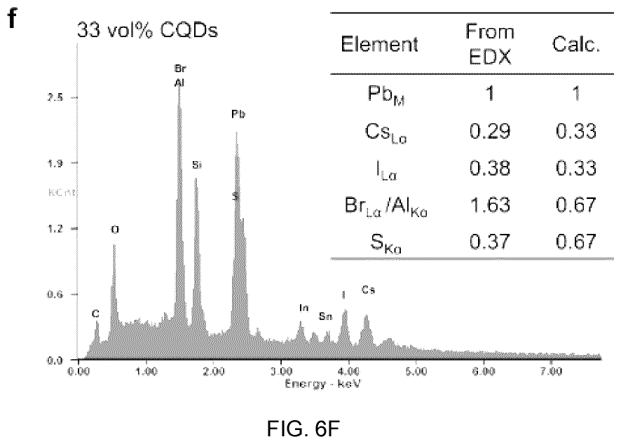

The hybrid films were prepared using CsPbBrₓI₃₋ₓ matrix solutions combined with pre-exchanged CQDs (FIGS. 5A to 5F). By controlling the weight ratio of CQD to perovskite, we tuned the amount of perovskite matrix and the expected average dot-to-dot distance¹⁴. The hybrid ink was deposited by spin-coating to achieve an optimized thickness, followed by an annealing process to crystallize the matrix and remove solvent residue. Elemental mapping from energy dispersive X-ray spectroscopy (EDX) in scanning electron microscopy (SEM) indicates a uniform elemental distribution in the hybrid films (FIGS. 5C to 5F, FIG. 6A to 6F).

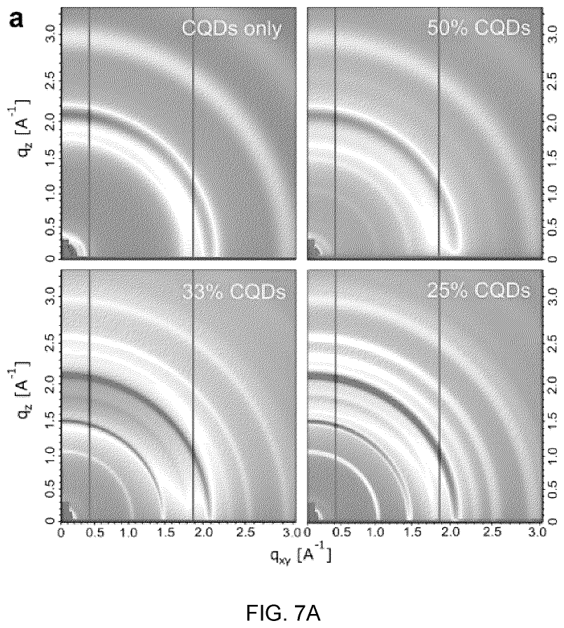

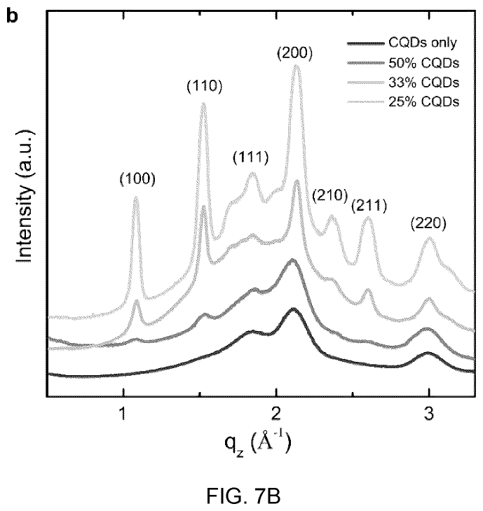

Synchrotron high-resolution X-ray diffraction (XRD) measurements were carried out to elucidate the composition and crystal structure of the hybrid films (FIGS. 1C, 7A, 7B). In this study, CQD films with CsPbBrI₂ and CsPbBr₂I matrix were studied. XRD demonstrates that as-synthesized perovskite and CQDs are each in the cubic phase: CsPbBrI₂ shows a 1% lattice mismatch with PbS CQDs; in contrast, CsPbBr₂I and PbS show complete agreement in lattice planes (FIG. 7B).

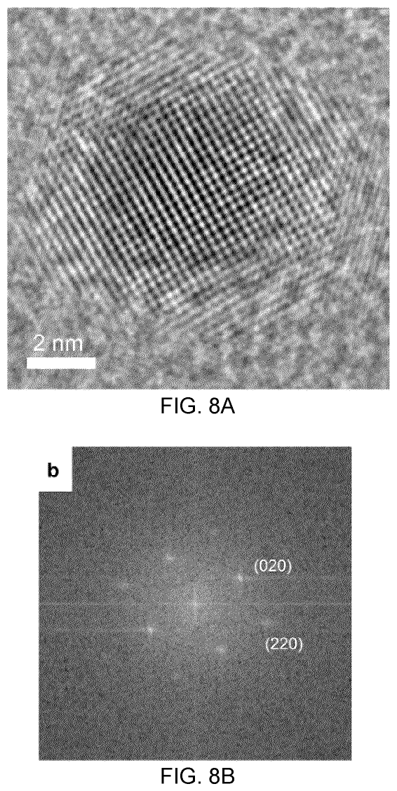

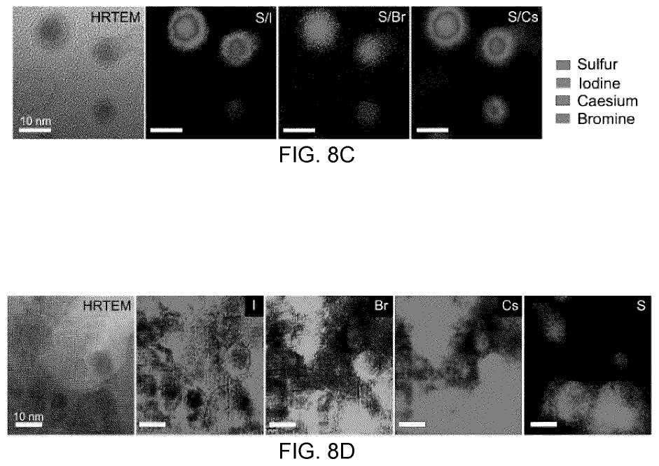

High-resolution transmission electron microscopy (HRTEM) was used to ascertain further the crystal structure and identify the orientation of perovskites and CQDs relative to one another (FIGS. 1D, 1E, 8A, 8B). The real space images show that a perovskite shell forms at high CQD concentration and inherits the crystalline orientation of its associated dot (FIG. 1D). No spacing differences between core CQD and perovskite shell were observed from TEM images, indicating epitaxial orientational alignment at two dominant facets. Lattice fringes of 3.4±0.1 Å and 3.0±0.1 Å spacing are ascribed to (11̅1) and (200) planes, respectively, both for the CQDs and for the matrix, in agreement with Fast Fourier Transform (FFT) images (FIGS. 8A, 8B). As the amount of perovskite increases, the shell grows thicker and forms a continuous matrix with dots embedded inside (FIG. 1E). The incorporation of CQDs is further confirmed via elemental distribution analysis using electron energy-loss spectroscopy mapping (FIGS. 8C, 8D).

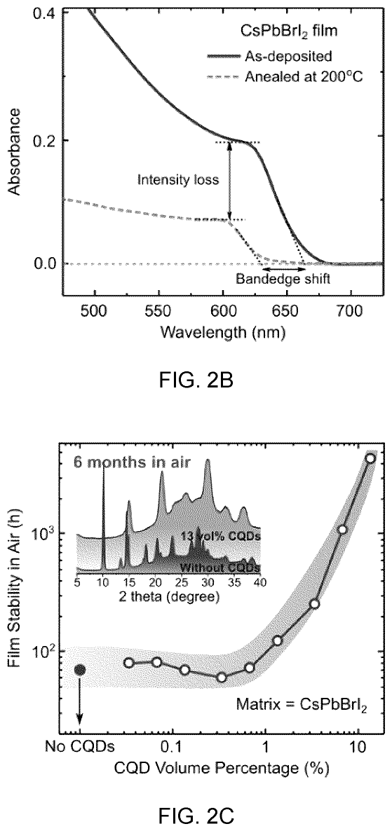

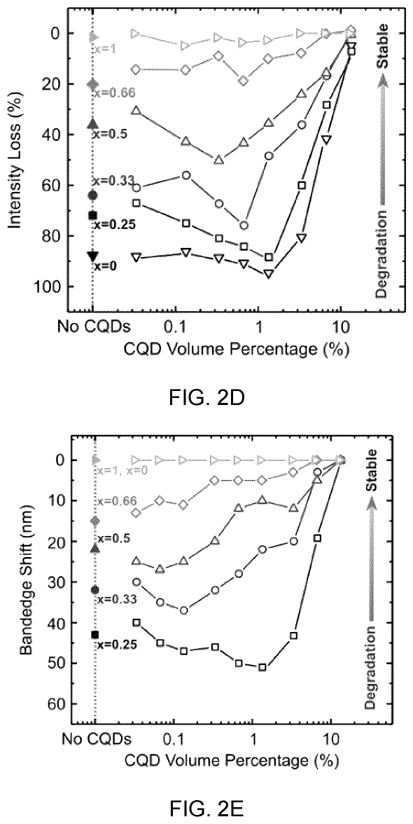

The effect of embedded dots on perovskite lifetime was then investigated. In pristine CsPbBrₓI₃₋ₓ films, phase transition and phase segregation are detrimental to their stability. An α-phase (dark) to δ-phase (transparent) transition occurs, particularly in films with low Br content, at low temperatures (e.g. room atmosphere), leading to a loss in the amplitude of film absorption. Phase segregation occurs when mixed-halide perovskite films are annealed in air at high temperatures, a result of the increased ion migration triggered by oxygen and heat. This results in separated Br-rich phases and I-rich phases (FIG. 2A), leading to a blueshift in the absorption edge. Film degradation is thus readily witnessed via an intensity loss and bandedge shift in absorption spectra (FIG. 2B).

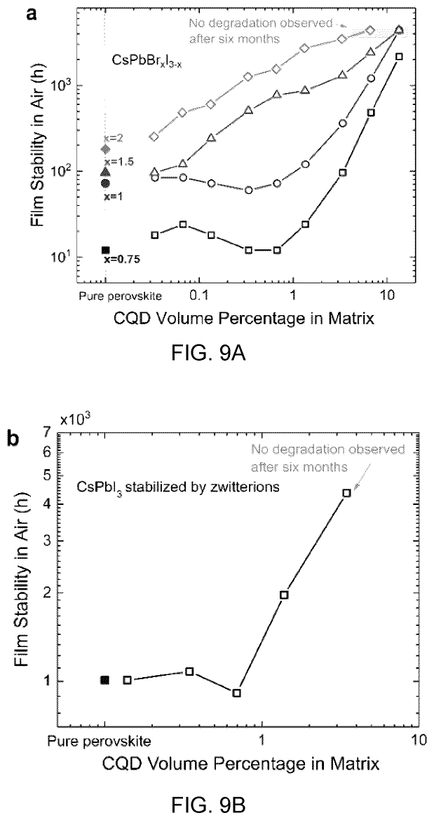

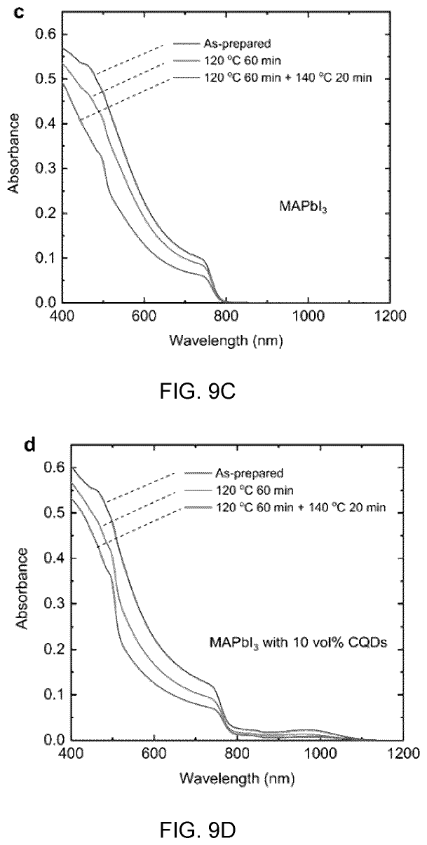

A volume fraction lower than 15% of CQDs was used in order to ensure uniform coverage and maintain the original grain size of perovskites (FIGS. 5C to 5F). Studies reveal that the incorporation of CQDs improves the stability of perovskite films by an order of magnitude (FIG. 9A). The inventors associate the improved stability with the high formation energy of the α/δ-phase interface. For CsPbBrI₂ perovskite, room-ambient stability is enhanced from three days to more than six months when 13 vol % CQDs are incorporated (FIG. 2C). XRD measurements confirm that the cubic crystal structure remains unchanged after six months storage. This strategy is also compatible with previously-reported methods² and allows for greater than six months' stability in lattice-anchored CsPbI₃ (FIG. 9B).

The thermal stability of perovskites in air was then investigated. The absorption spectra of films were recorded before and after annealing in air at 200° C. for five hours (FIGS. 2D and 2E). Phase segregation occurs in pristine perovskite films within 30 min. However, this is largely suppressed when CQDs are integrated at a concentration above 6%: no film degradation is observed following five hours of annealing in air. The extent of improvement in film stability was found to depend strongly on the lattice mismatch between CQDs and perovskite. For CQD:CsPbBr₂I samples in which ˜zero lattice mismatch is achieved, reduced intensity loss and bandedge shift in absorption spectra are detected with increasing CQD concentrations, showing a gradual improvement in film stability. When lattice mismatch increases as we decrease the Br ratio, a larger strain is generated at interfaces. The stability vs. increasing CQD concentration follows a V-shaped trend, first declining and then improving. We explain this by invoking interfacial strain between perovskites and CQDs: an unstrained CQD/perovskite interface is the most energetically favourable; and a certain amount of elastic strain can be accommodated without generating dislocations or defects¹⁷.

In a lattice-mismatched system, a lower CQD concentration results in more perovskite layers between neighbouring CQDs and consequently increases the effects of strain. At low CQD loading, the interfacial strain is large enough to generate atomic dislocations. In this case, CQD surfaces act as defect centers, and the increasing concentration thus leads to a decreased lifetime of the perovskite. When the dot-to-dot distance is small enough to keep the strain energy below the formation energy of dislocations¹⁸, the stability is increased. As a result, a perovskite matrix with the larger lattice mismatch demands a higher CQD concentration to anchor the atoms and achieve improved lifetime (FIG. 2D, 2E). This result is consistent with the observed phase stability measured at room temperature (FIG. 9A).

The thermal stability of CQDs was investigated when a perovskite matrix is added. The inventors hypothesis was that passivation provided by the perovskite matrix could inhibit oxidation and aggregation of CQDs.

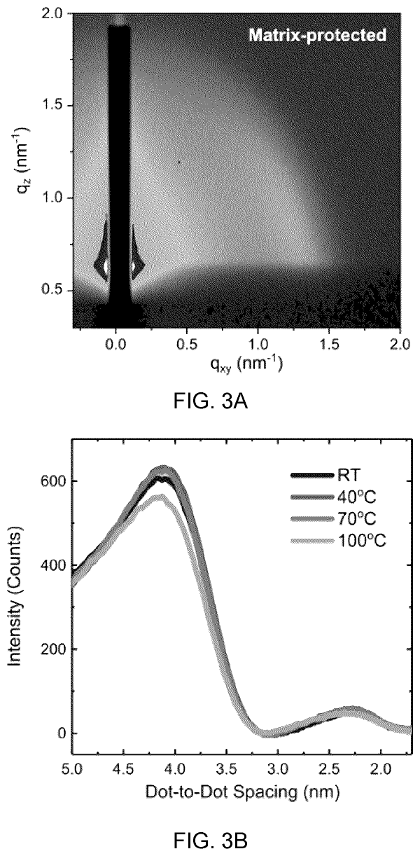

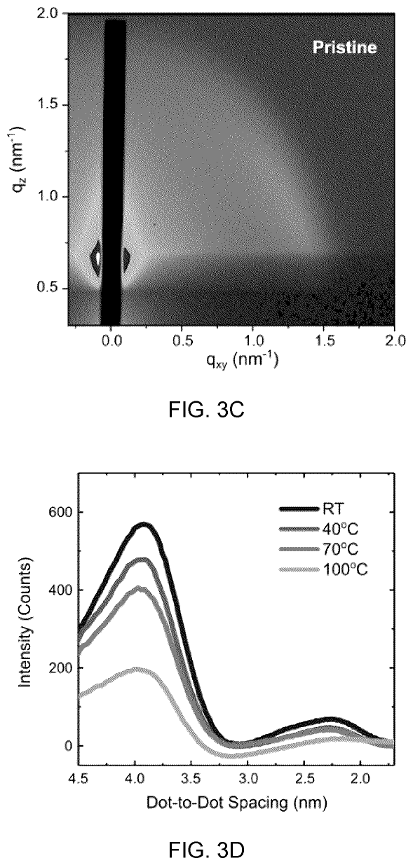

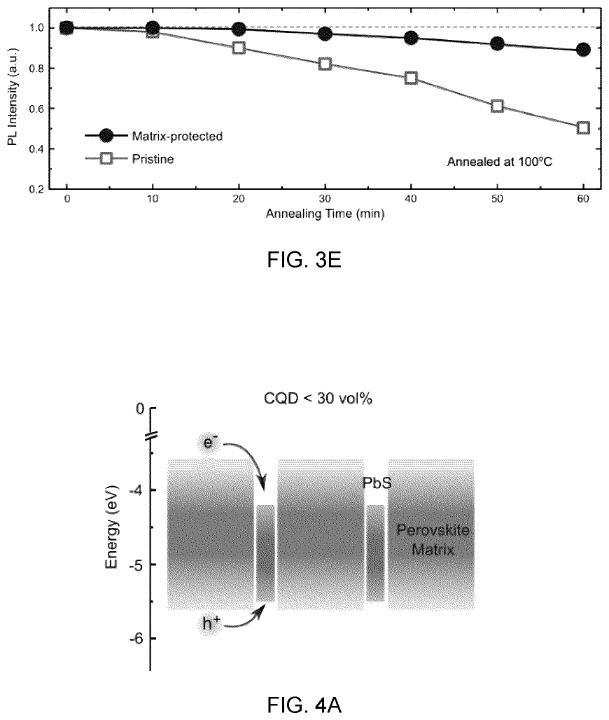

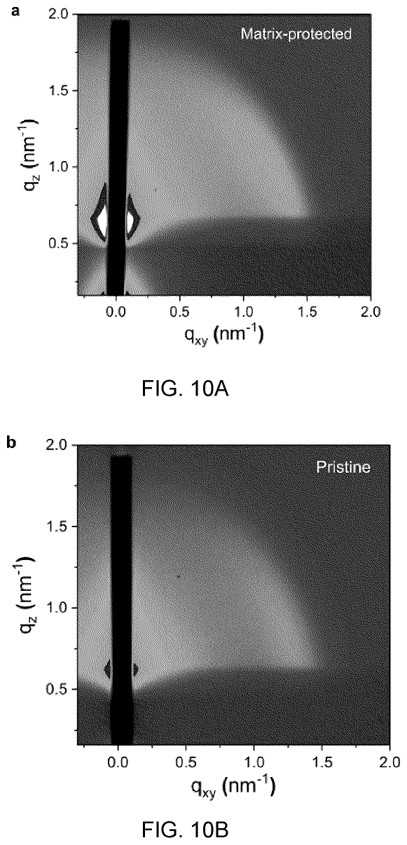

In-situ grazing incident small-angle X-ray scattering (GISAXS) measurements were carried out to track changes in CQD packing density and uniformity at elevated temperatures (FIG. 3). Before annealing, pure and hybrid films each present a hexagonal diffraction pattern, indicating an orientational ordering of CQDs (FIGS. 10A, 10B). Azimuthal integration of the diffraction pattern (FIGS. 3B, 3D) reveals changes at elevated temperatures. It reveals that pure CQD films begin to show aggregation at relatively low temperatures (40° C.), and Zo lose packing uniformity rapidly as temperature increases. By contrast, no degradation is observed below 100° C. in the matrix-protected films. Following annealing, the hexagonal pattern is no longer observable in pure CQD films; whereas it is sustained in hybrid films (FIGS. 3A, 3C).

Photoluminescence (PL) studies affirm this finding: we recorded the PL intensity of films following annealing under 100° C. for different periods of time (FIG. 3E). The pure CQD film shows a rapid PL quenching and loses half of the intensity after an hour, which is consistent with a previous report¹⁹. In contrast, matrix-protected films maintain 90% of the initial value following annealing.

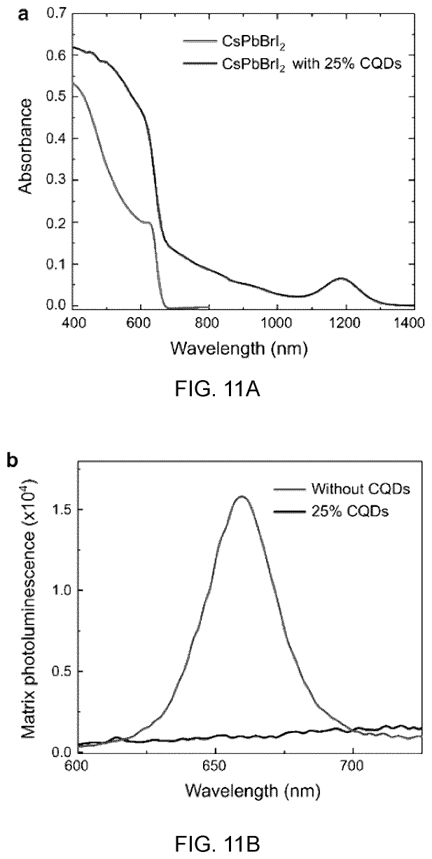

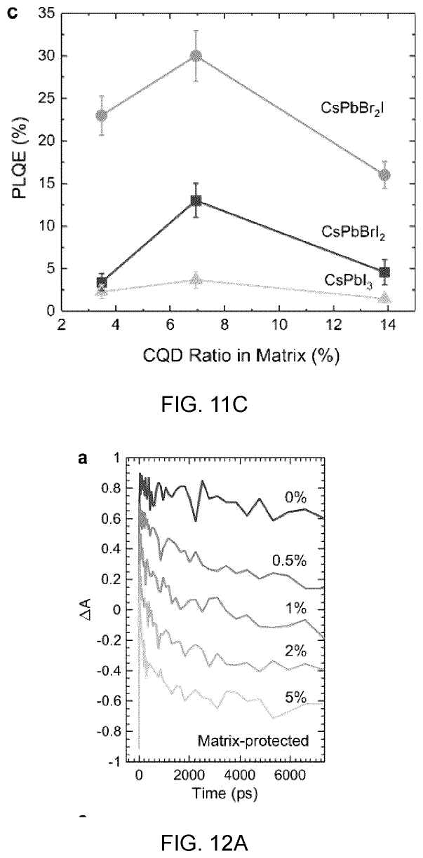

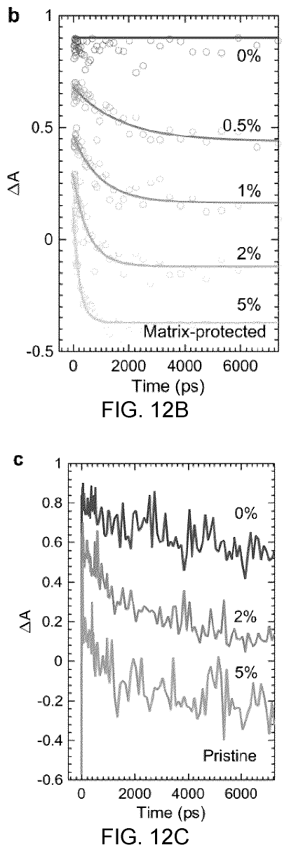

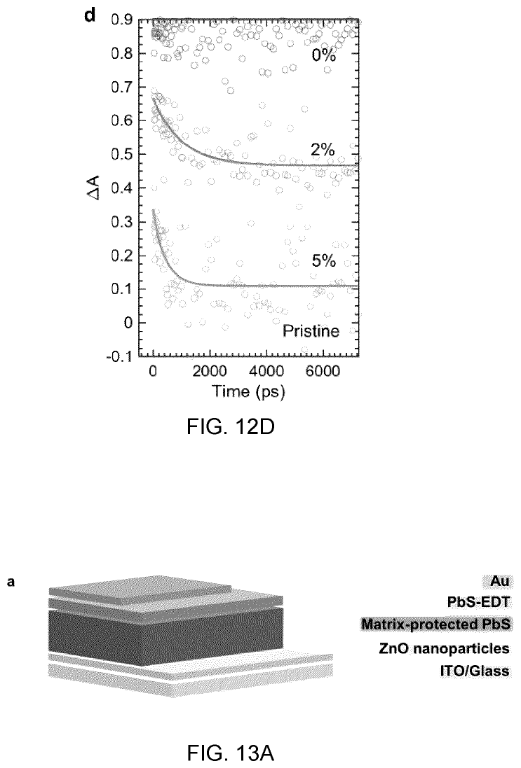

In addition to evincing improved stability, the hybrid materials also show improved optoelectronic properties. The quantum dots used in this study, which have bandgaps ranging from 1.1 eV and 1.3 eV, were predicted to experience both hole and electron confinement by the CsPbBrₓI₃₋ₓ matrix, i.e. to the lower-bandgap inclusions within a type-I heterostructure (FIGS. 4A, 11A). When the perovskite matrix is excited using light having a photon energy that exceeds its bandgap, photocarriers are generated in the perovskite and transfer from matrix to the CQDs. This contributes to an enhanced near-infrared PL emission compared to the situation in which excitons are generated in CQDs only. At high CQD loading, the carrier transfer efficiency exceeds 87±3% (FIG. 4D, Table 1). A complete quenching of the perovskite signal is also observed, consistent with efficient carrier transfer (FIG. 11B).

The PL increases as the concentration of CQDs is reduced, and reaches its maximum in films with 7 vol % CQDs (FIG. 11C). We studied the photoluminescence quantum efficiency (PLQE) of films having different matrix compositions to verify the effect of an epitaxially grown matrix on interface passivation (FIG. 4E). The PLQE of CQDs increases with a higher bromine ratio in the matrix and peaks at 67% bromine concentration, the value at which lowest lattice mismatch is achieved (ε<0.2%). The lattice-matched matrix augments surface passivation of CQD solids and leads to a film PLQE of 30±3% at the infrared wavelength, equivalent to the PLQE of CQD solution. The film retains its initial value of PLQE after it is stored in air for one week. By contrast, the film PLQE is below 15% when the lattice mismatch is above 0.5%.

An investigating was conducted into whether the inorganic matrix, with its modest conduction band (CB) and valence band (VB) offsets relative to the dots, could improve carrier mobility relative to prior CQD solids. Pure CQD films exhibit random close packing with a theoretical maximum volume fraction of about 64%. This corresponds to about 30% of film volume that—in the absence of matrix—can be occupied by high-barrier vacuum (FIG. 4C). The inventors postulated that, when the perovskite matrix was added at a level sufficient to fill substantially these voids, this could ease transport via barrier lowering (FIG. 4B).

Transient absorption spectroscopy (TAS) studies were used to obtain carrier mobility, and observed a doubling in mobility in the matrix-infiltrated CQDs with 15 vol % CsPbBr₂I compared to pristine CQD films (FIG. 4E, 12A to 12D).

We then pursued the realization of CQD solar cells with the best matrix-infiltrated active layer. We relied on a previously-reported photovoltaic device architecture³ (FIG. 13A). The matrix-protected CQDs demonstrate improved photovoltaic properties compared to controls, generating higher current density and open-circuit voltage (FIG. 13B, 13C). When we used 15 vol % CsPbBr₂I matrix, the devices show a reproducibly increased performance relative to controls, and a champion PCE of 12.6%. They also exhibit significantly enhanced photostability, Zo retaining 95% of their initial PCE following two hours of continuous AM1.5G illumination, unencapsulated (FIG. 13D). The matrix-free controls, on the other hand, degrade to 70% of their initial PCE value within an hour. This result supports the contention that the lattice-matching perovskite matrix provides improved surface passivation and lowers the energy barrier for carrier hopping.

In summary, the present disclosure provides a lattice anchoring strategy that provides solution-processed semiconductor materials exhibiting increased stability relative to either constituent phase. By incorporating CQDs in CsPbBrₓI₃₋ₓ perovskites the formation of the undesired δ-phase configuration was suppressed. This significantly increased the lifetime of α-phase cesium lead halide perovskite including under 200° C. multi-hour thermal stress. The epitaxially-oriented perovskite matrix also provides excellent passivation to CQD surfaces, inhibiting attack from oxygen and preventing CQD fusion at elevated temperatures. In addition, the perovskite matrix lowers the energetic barrier to carrier transport, contributing to a doubling in carrier mobility.

### REFERENCES

1. Beal, R. E. et al. Cesium lead halide perovskites with improved stability for tandem solar cells. J. Phys. Chem. Lett. 7, 746-751 (2016).
2. Wang, Q. et al. Stabilizing the α-phase of CsPbI₃ perovskite by sulfobetaine zwitterions in one-step spin-coating films. Joule 1, 371-382 (2017).
3. Liu, M. et al. Hybrid organic-inorganic inks flatten the energy landscape in colloidal quantum dot solids. Nat. Mater. 16, 258-263 (2017).
4. Zhou, J., Liu, Y., Tang, J. & Tang, W. Surface ligands engineering of semiconductor quantum dots for chemosensory and biological applications. Mater. Today 20, 360-376 (2017).
5. Tan, Z.-K. et al. Bright light-emitting diodes based on organometal halide perovskite. Nat. Nanotechnol. 9, 687-692 (2014).
6. Chuang, C.-H. M., Brown, P. R., Bulović, V. & Bawendi, M. G. Improved performance and stability in quantum dot solar cells through band alignment engineering. Nat. Mater. 13, 796-801 (2014).
7. Katan, C., Mohite, A. D. & Even, J. Entropy in halide perovskites. Nat. Mater. 17, 377-379 (2018).
8. Yang, W. S. et al. High-performance photovoltaic perovskite layers fabricated through intramolecular exchange. Science 348, 1234-1237 (2015).
9. National Renewable Energy Laboratory. Photovoltaic research. http://www.nrel.gov/ncpv/images/efficiency_chart.jpg.
10. Eperon, G. E. & Ginger, D. S. B-Site metal cation exchange in halide perovskites. ACS Energy Lett. 2, 1190-1196 (2017).
11. Li, B. et al. Surface passivation engineering strategy to fully-inorganic cubic CsPbI₃ perovskites for high-performance solar cells. Nat. Commun. 9, 1076 (2018).
12. Ihly, R., Tolentino, J., Liu, Y, Gibbs, M. & Law, M. The photothermal stability of PbS quantum dot solids. ACS Nano 5, 8175-8186 (2011).
13. Zhang, X. et al. Inorganic CsPbI₃ perovskite coating on PbS quantum dot for highly efficient and stable infrared light converting solar cells. Adv. Energy Mater. 8, 1702049 (2018).
14. Ning, Z. et al. Quantum-dot-in-perovskite solids. Nature 523, 324-328 (2015).
15. Ning, Z. et al. Air-stable n-type colloidal quantum dot solids. Nat. Mater. 13, 822-828 (2014).
16. Dalven, R. Electronic structure of PbS, PbSe, and PbTe. Solid State Physics 28, 179-224 (1974).
17. Pinardi, K. et al. Critical thickness and strain relaxation in lattice mismatched II-VI semiconductor layers. J. Appl. Phys. 83, 4724-4733 (1998).
18. People, R. & Bean, J. C. Calculation of critical layer thickness versus lattice mismatch for GeₓSi₁₋ₓ/Si strained-layer heterostructures. Appl. Phys. Lett. 47, 322-324 (1985).
19. Keitel, R. C., Weidman, M. C. & Tisdale, W. A. Near-infrared photoluminescence and thermal stability of PbS nanocrystals at elevated temperatures. J. Phys. Chem. C 120, 20341-20349 (2016).

1. A composite material, comprising:
crystalline or polycrystalline particles embedded in a crystalline or polycrystalline shell material, said crystalline or polycrystalline shell material having first and second crystal phase structures, said first crystal structure being less thermodynamically stable than said second crystal phase structure, said composite material characterized in that said crystalline or polycrystalline shell material in said composite material exhibiting said first crystal phase structure and wherein the crystalline or polycrystalline particles include lattice planes and the first crystal structure of said crystalline or polycrystalline shell material include lattice planes, said crystalline or polycrystalline particles and said crystalline or polycrystalline shell material being selected so that any lattice mismatch between the two lattice planes does not exceed 10%, said crystalline or polycrystalline particle lattice planes and said crystalline or polycrystalline shell material lattice planes being substantially aligned such that the crystalline or polycrystalline particles and said crystalline or polycrystalline shell material are substantially atomically aligned, and wherein said crystalline or polycrystalline particles are present in the crystalline or polycrystalline shell material in a volume ratio from about 0.1 vol % to about 90 vol %.

2. The composite material according to claim 1, wherein said crystalline or polycrystalline particles and said crystalline or polycrystalline shell material being selected so that any lattice mismatch between the two lattice planes does not exceed about 4%.

3. The composite material according to claim 1, wherein said crystalline or polycrystalline particles are present in the crystalline or polycrystalline shell material in a volume ratio from about 1 vol % to about 90%.

4. The composite material according to claim 1, wherein said crystalline or polycrystalline shell material has a thickness in a range from about 0.5 nm to about 50 nm.

5. The composite material according to claim 1, wherein said crystalline or polycrystalline particles have size in a range from about 1 nm to 100 nm.

6. The composite material according to claim 1, wherein said crystalline or polycrystalline particles are lead chalcogenide based colloidal quantum dots, and wherein said crystalline or polycrystalline shell material is an inorganic perovskite.

7. The composite material according to claim 6, wherein said colloidal quantum dots are selected from the group consisting of lead sulphide (PbS) and lead selenide (PbSe).

8. The composite material according to claim 6, The composite material according to claim 6 or 7, wherein said inorganic perovskite shell material is selected from the group consisting of cesium (Cs), lead (Pb) halides.

9. The composite material according to claim 6, wherein said perovskite is selected from the group consisting of any combination of cesium (Cs), rubidium (Rb), lead (Pb), chloride, bromide and iodide.

10. The composite material according to claim 1, wherein said crystalline or polycrystalline particles are lead chalcogenide based colloidal quantum dots, and wherein said crystalline or polycrystalline shell material is an inorganic perovskite shell and wherein said composite material is incorporated into a photovoltaic cell, and wherein said collodial quantum dots are present in the perovskite shell in a volume ratio from about 80 vol % to about 90 vol %, said photovoltaic cell characterized in that the light absorbing component is the quantum dots.

11. The composite material according to claim 10, wherein said colloidal quantum dots are selected from the group consisting of lead sulphide (PbS) and lead selenide (PbSe).

12. The composite material according to claim 10, wherein said perovskite is selected from the group consisting of any combination of cesium (Cs), lead (Pb) halides.

13. The composite material according to claim 1, wherein said crystalline or polycrystalline particles are lead chalcogenide based colloidal quantum dots, and wherein said crystalline or polycrystalline shell material is an inorganic perovskite shell and wherein said composite material is incorporated into a photovoltaic cell, and wherein said collodial quantum dots are present in the inorganic perovskite shell in a volume ratio from about 0.5 vol % to about 5 vol %, said photovoltaic cell characterized in that the light absorbing component is the perovskite shell.

14. The composite material according to claim 13, wherein said colloidal quantum dots are selected from the group consisting of lead sulphide (PbS) and lead selenide (PbSe).

15. The composite material according to claim 13, wherein said perovskite shell is selected from the group consisting of cesium (Cs), lead (Pb) halides.

16. The composite material according to claim 1, wherein said crystalline or polycrystalline particles are lead chalcogenide based colloidal quantum dots, and wherein said crystalline or polycrystalline shell material is an inorganic perovskite and wherein said composite material is incorporated into a light emitting diode device, and wherein said colloidal quantum dots are present in the perovskite shell in a volume ratio from about 10 vol % to about 25 vol %, and wherein said colloidal quantum dots are the light emitting medium.

17. The composite material according to claim 16, wherein said colloidal quantum dots are selected from the group consisting of lead sulphide (PbS) and lead selenide (PbSe).

18. The composite material according to claim 16, The composite material according to claim 16 or 17, wherein said perovskite is selected from the group consisting of cesium (Cs), lead (Pb) halides.

19. The composite material according to claim 10, wherein said perovskite is selected from the group consisting of any combination of cesium (Cs), rubidium (Rb), lead (Pb), chloride, bromide and iodide.

20. The composite material according to claim 10, wherein colloidal quantum dots have size in a range from about 1 nm to about 100 nm.

21. The composite material according to claim 10, characterized in that the colloidal quantum dots are stabilized, by the inorganic perovskite shell, against thermally activated oxidation above room temperature up to a temperature of about 200° C.
